(19) United States
(12) Patent Application Publication
(10) Pub. No.: US 2024/0282032 A1
(43) Pub. Date: Aug. 22, 2024

(54) METHODS FOR SIMULATING QUASI-STATIC VOLUME PRESERVING DEFORMATION

(71) Applicant: Michael Alexander EWERT, Victoria (CA)

(72) Inventor: Michael Alexander EWERT, Victoria (CA)

(73) Assignee: Digital Domain Virtual Human (US), Inc., Los Angeles, CA (US)

(21) Appl. No.: 18/625,164

(22) Filed: Apr. 2, 2024

Related U.S. Application Data
(63) Continuation of application No. PCT/CA2022/051477, filed on Oct. 6, 2022.
(60) Provisional application No. 63/256,485, filed on Oct. 15, 2021.

(51) Int. Cl. G06T 13/20; G06T 7/73; G06T 17/20; G06T 19/20

(52) U.S. Cl. CPC G06T 13/20; G06T 7/75; G06T 17/205; G06T 19/20; G06T 2219/2021

(57) ABSTRACT

A computer-implemented method of simulating deformation of a solid body comprises: defining a mesh representation of the solid body, the mesh representation comprising a plurality of mesh elements, each mesh element defined by a plurality of vertices; receiving a material model comprising one or more material properties of the solid body; and for each of the plurality of vertices defining the plurality of mesh elements, determining a subsequent position of the vertex at a subsequent time step, wherein determining the subsequent position comprises: defining a current position and a current velocity of the vertex; defining a positional constraint of the vertex based on the material model; and computing a subsequent position of the vertex based on at least the current position, the current velocity and the positional constraint.

### REFERENCE TO RELATED APPLICATIONS

This application is a continuation of Patent Cooperation Treaty (PCT) application No. PCT/CA2022/051477 having an international filing date of 6 Oct. 2022, which in turn claims priority from, and for the purposes of the United States the benefit under 35 USC 119 in connection with, U.S. application No. 63/256,485 filed 15 Oct. 2021. All of the applications in this paragraph are hereby incorporated herein by reference.

### TECHNICAL FIELD

This invention relates generally to computer animation, and more particularly to systems and methods for simulating volume preserving object deformation based on the use of a Finite Element Method (FEM) material model in combination with a symplectic integrator.

### BACKGROUND

Early digital animation involved artists creating individual image frames in a digital environment to produce an ordered sequence of digital image frames. An advantage of these early digital animation processes is that elements of a digital image frame (such as a relatively static background scene, for example) could easily be copied onto other image frame(s), thereby speeding up the process of creating a sequence of digital image frames. Relatively recently, 2-dimensional and 3-dimensional computer-based graphic simulations have been developed which use computer-based material models to simulate the movement of objects as between digital image frames and to thereby provide data which can be used to animate moving objects within a sequence of digital image frames.

There is a desire to provide computer-based simulation and/or animation of musculoskeletal systems (and/or similar systems) comprising a rigid-body (e.g. skeletal) system and a system of deformable, but volume-preserving solids (e.g. soft tissue, such as muscle and fat), which interacts with the rigid-body system. Such animation may simulate movement of the musculoskeletal system. Such simulations may be used to generate corresponding animations of the musculoskeletal systems and/or similar systems, which animations comprise ordered sequences of complete or partial digital image frames often referred to as Computer-Generated Imagery (CGI) video data, CGI animation data or CGI moving picture data. There is a general desire that such animations, when rendered by suitable computer-based graphics engines, provide musculoskeletal animation that appears realistic to viewers when rendered. There is a corresponding general desire to minimize the computation expense associated with performing such simulations and/or generating such animations.

Much research on simulating muscle behaviour in the field of CGI relies on numerical methods such as the Finite Element Method (FEM) or Finite Volume Method (FVM). These approaches generally involve subdividing a surface of a solid body into a mesh. These methods solve for deformation in the solid body, given the application of external forces, at the locations of the various nodes (vertices) of the mesh. Such approaches produce realistic results, but their solutions typically require a high computational cost and are complex to set up, such that they are not generally suitable for real-time or quasi-real time simulation.

Position Based Dynamics (PBD) is a technique described by M. Mueller et al. Position Based Dynamics. Journal of Visual Communication and Image Representation, Volume 18, Issue 2, April 2007 pp 109-118 and in U.S. Pat. No. 7,616,204, both of which are hereby incorporated herein by reference. PBD offers a fast and controllable solution to simulate surfaces and volumes. PBD is based on the principle of projecting constraints associated with a few degrees of freedom to a set of vertices. Based on the constraints and current and previous positions of the vertices, the positions of the vertices are updated according to a Verlet integration step. However, the use of PBD and its methods of constraint projection do not provide control over the material stiffness and do not respect the Poisson effect. Consequently, PBD techniques do not preserve volume when the simulated volume is being deformed, which can result in un-realistic simulations, especially in the simulation of musculoskeletal systems, where there is a desire to preserve the volume of soft tissue, such as muscle or fat.

Extended position-based dynamics (XPBD) is a technique described in Macklin, M. et al. (2016). XPBD: Position-Based Simulation of Compliant Constrained Dynamics. Proceedings of the 9th International Conference on Motion in Games, pp. 49-54 (which is hereby incorporated herein by reference). XPBD is an extension to PBD which is proposed to more accurately simulate material models via a technique known as compliance. However, XPBD suffers from the same simulation artifacts as PBD when applied to quasi-static simulation scenarios.

One commercially available prior art musculoskeletal animation system is the Maya™ Muscle system provided by Autodesk Inc. As understood by the inventors, the Maya™ Muscle animation system is based on PBD to achieve dynamic muscle effects, as opposed to physics-based volumetric muscle simulation involving FEM or FVM and does not include volume-preservation or close-contact constraints. As a consequence, animations generated using the Maya™ system can appear relatively un-realistic to viewers. Another prior art musculoskeletal animation system is described by Lee et al. in Comprehensive biomechanical modeling and simulation of the upper body. ACM Transactions on Graphics (TOG), 28(4):99, 2009. As understood by the inventors, the Lee et al. system used a physics-based approach for modelling the shapes of muscles, but the Lee et al. model uses a muscle activation model using line segments to represent muscles and, consequently, can output soft tissue shapes that do not appear realistic when rendered.

There is a general desire for musculoskeletal simulation systems for use in CGI which feature improved volume preservation, produce fewer simulation artifacts, are computationally efficient, and/or are well adapted to collision handling.

The foregoing examples of the related art and limitations related thereto are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One aspect of the invention provides a computer-implemented method for simulating deformation of a solid body. The method comprises: defining and/or receiving a mesh representation of the solid body, the mesh representation comprising a plurality of vertices; defining and/or receiving a material model comprising one or more parameters for modeling one or more corresponding material properties of the solid body; for each time step in a simulation comprising one or more time steps: determining a subsequent position for each vertex among the plurality of vertices at a subsequent time step, wherein determining the subsequent position for each vertex among the plurality of vertices at the subsequent time step comprises: defining and/or receiving a current position and a current velocity of each vertex among the plurality of vertices; defining a positional constraint for each vertex among the plurality of vertices based at least in part on the material model; and estimating the subsequent position of each vertex among the plurality of vertices based at least in part on the current position of the vertex, the current velocity of the vertex and the positional constraint for the vertex.

Another aspect of the invention provides a computer-implemented method of simulating deformation of a solid body, the method comprising: defining a mesh representation of the solid body, the mesh representation comprising a plurality of polyhedral mesh elements, each polyhedral mesh element defined by a plurality of vertices, receiving a material model comprising one or more material properties of the solid body; for each of the plurality of vertices defining the plurality of polyhedral mesh elements, determining a subsequent position of the vertex at a subsequent time step, wherein determining the subsequent position of the vertex at the subsequent time step comprises: defining a current position and a current velocity of the vertex; defining a positional constraint of the vertex based on the material model; and computing a subsequent position of the vertex based on at least the current position, the current velocity and the positional constraint.

Another aspect of the invention provides a system for simulating deformation of a solid body, the system comprising a processor configured to: define and/or receive a mesh representation of the solid body, the mesh representation comprising a plurality of vertices; define and/or receive a material model comprising one or more parameters for modeling one or more corresponding material properties of the solid body; for each time step in a simulation comprising one or more time steps: determine a subsequent position for each vertex among the plurality of vertices at a subsequent time step, wherein determining the subsequent position for each vertex among the plurality of vertices at the subsequent time step comprises: defining and/or receiving a current position and a current velocity of each vertex among the plurality of vertices; defining a positional constraint for each vertex among the plurality of vertices based at least in part on the material model; and estimating the subsequent position of each vertex among the plurality of vertices based at least in part on the current position of the vertex, the current velocity of the vertex and the positional constraint for the vertex.

Another aspect of the invention provides a system for simulating deformation of a solid body, the system comprising a processor, the processor configured to: define a mesh representation of the solid body, the mesh representation comprising a plurality of polyhedral mesh elements, each polyhedral mesh element defined by a plurality of vertices, receive a material model comprising one or more material properties of the solid body; for each of the plurality of vertices defining the plurality of polyhedral mesh elements, determe a subsequent position of the vertex at a subsequent time step, wherein determining the subsequent position of the vertex at the subsequent time step comprises: defining a current position and a current velocity of the vertex; defining a positional constraint of the vertex based on the material model; and computing a subsequent position of the vertex based on at least the current position, the current velocity and the positional constraint.

Defining the positional constraint may comprise defining the positional constraint for each vertex among the plurality of vertices in a form of a position update which relates a position of the vertex at a first time step to a position of the vertex at a later time step.

The positional constraint for each vertex among the plurality of vertices may have a form of (I+ΔtK̅+γK̅)xᵢ₊=xᵢ+Δtνᵢ+γK̅xᵢ as described herein in connection with equation (6).

Determining the subsequent position for each vertex among the plurality of vertices at the subsequent time step may comprise application of a position based dynamics (PBD) integrator.

Determining the subsequent position for each vertex among the plurality of vertices at the subsequent time step may comprise: computing an initial updated position estimate for each vertex among the plurality of vertices at the subsequent time step based at least in part on the current position and the current velocity of the vertex; defining one or more position based dynamics (PBD) constraints; in each iteration of an iterative constraint projection process: projecting the PBD constraints to arrive at PBD-constrained vertex position estimates, wherein projecting the PBD constraints comprises, for each vertex among the plurality of vertices, starting with the initial updated position estimate and moving a position of the vertex in directions which tend to satisfy the one or more PBD constraints to provide a PBD-constrained vertex position; applying the positional constraints to arrive at FEM-constrained position estimates, wherein applying the positional constraints comprises, for each vertex among the plurality of vertices, starting with the PBD-constrained vertex position and moving the position of the vertex in accordance with the positional constraint to provide a FEM-constrained vertex position; at the conclusion of the iterative constraint projection process determining the subsequent position for each vertex among the plurality of vertices at the subsequent time step to be the FEM-constrained vertex position of the vertex after a last iteration of applying the positional constraints.

Determining the subsequent position for each vertex among the plurality of vertices at the subsequent time step may comprise: computing an initial updated position estimate for each vertex among the plurality of vertices at the subsequent time step based at least in part on the current position and the current velocity of the vertex; defining one or more constraints, wherein the one or more constraints include the positional constraints; projecting the one or more constraints, wherein projecting the one or more constraints comprises, for each vertex among the plurality of vertices, starting with the initial updated position estimate and iteratively moving a position of the vertex to satisfy the one or more constraints, with each iteration providing an updated vertex position; determining subsequent position for each vertex among the plurality of vertices at the subsequent time step to be the updated vertex position of the vertex after the last iteration of moving the position of the vertex to satisfy the one or more constraints.

A number of iterations in the iterative constraint projection process may be based on a number of iterations experimentally determined to satisfy one or more criteria. The number of iterations experimentally determined to satisfy one or more criteria may be user-configurable by setting a first threshold number of iterations, qualitatively or quantitatively assessing convergence, and then setting a second threshold number (larger than the first threshold number) of iterations and continuing to iteratively perform the constraint projection process until reaching the second threshold number of iterations.

Defining the positional constraint for each vertex among the plurality of vertices based at least in part on the material model may comprise: modifying a Störmer-Verlet integrator by representing a velocity term using an implicitly updated position state; combining an implicit Euler integrator comprising the material model with the modified Störmer-Verlet integrator; and solving a linear system of the combined integrators to obtain a position update equation representing the positional constraint based on the material model.

Representing the velocity term of the Störmer-Verlet integrator using an implicitly updated position state may have the form of

$${v}_{i + 1} = \frac{( {x}_{i + 1} - {x}_{i} )}{Δ t}$$

as described here in connection with equation (3).

The implicit Euler integrator of an FEM solver may have the form of νᵢ₊₁=νᵢ−KM⁻¹Δtxᵢ₊₁−γKM⁻¹Δtνᵢ₊₁ as described herein in connection with equation (4).

The linear system of the combined integrators may have the form of (I+ΔtK̅+γK̅)xᵢ₊₁=xᵢ+Δtνᵢ+γK̅xᵢ as described herein in connection with equation (6).

The material model may comprise a material model suitable for use in implicit FEM.

The positional constraint based on the material model may enforce one or more of: Lamé parameters; Young's modulus; and Poisson's ratio; of the solid body.

The material model may comprise a corotated linear elasticity model. The material model may comprise a Cauchy elastic model. The material model may comprise a hyperelastic material model.

Another aspect of the invention provides a computer program product embodied on a non-transitory medium bearing instructions which when executed by a suitable configured processor cause the processor to perform any of the methods described herein.

It is emphasized that the invention relates to all combinations of the above features, even if these are recited in different claims or aspects.

In addition to the exemplary aspects and embodiments described above, further aspects and embodiments will become apparent by reference to the drawings and by study of the following detailed descriptions.

### BRIEF DESCRIPTION OF THE DRAWINGS

Exemplary embodiments are illustrated in referenced figures of the drawings. It is intended that the embodiments and figures disclosed herein are to be considered illustrative rather than restrictive.

FIG. 1 is a flow chart depicting a method of performing a quasi-static FEM simulation (e.g. for animating or simulating a musculoskeletal system) according to a particular embodiment.

FIG. 2 is a flow chart depicting a method for determining node (vertex) displacements in a locally-implicit FEM simulation which may be used as part of the FIG. 1 method according to a particular embodiment.

FIG. 3 is a flow chart depicting a method for determining an optimal time step in a quasi-static FEM simulation according to a particular embodiment.

### DESCRIPTION

Throughout the following description specific details are set forth in order to provide a more thorough understanding to persons skilled in the art. However, well known elements may not have been shown or described in detail to avoid unnecessarily obscuring the disclosure. Accordingly, the description and drawings are to be regarded in an illustrative, rather than a restrictive, sense.

Aspects of the invention disclosed herein have applications in computer-generated imagery (CGI). The imagery resulting from such CGI may have applications in videos (e.g. films, television shows, etc.), video games, etc. Aspects of the invention may particularly have applications in simulating the movement of soft-tissue (e.g. skin, muscle, fat, etc.) of humans, animals, human-inspired objects (e.g. characters), animal-inspired objects (e.g. characters) and/or the like in CGI. For example, in generating a human character using CGI, aspects of this invention may simulate the movement of soft tissue (e.g. skin, muscle, fat, etc.) of the human character including movements like muscle contraction, elongation, tension and/or relaxation, skin movement associated with such muscle contraction, elongation, tension and/or relaxation, etc. In simulating such movement, the volume of the moved soft-tissue is preserved. For example in a muscle tension and relaxation event, the volume of such simulated tissue will change positions, but the volume itself will remain the same. This in turn may provide for more realistic simulations of CGI characters or other CG objects. Aspects of the invention may have applications in live-action animated motion pictures where CGI characters move based on simulation of muscle.

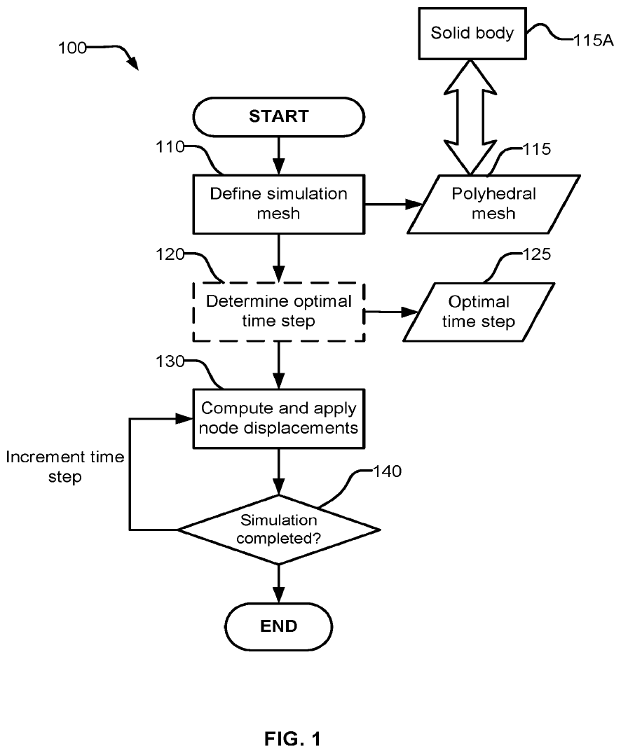

FIG. 1 schematically depicts a quasi-static FEM simulation method (e.g. for animating or simulating a musculoskeletal system) 100 according to an example embodiment of the invention. As used herein, a quasi-static deformation simulation involves a time-dependent simulation in which one or more loads acting on a deformable body are simulated. The load is considered to be applied slowly such that the object also deforms slowly (i.e. having a low strain rate). In this manner, the effects of inertia and residual velocity can be ignored. Method 100 begins at block 110, which comprises defining a polyhedral mesh 115 of a solid body 115A to be deformed. Mesh 115 comprises a plurality of polyhedra which, together, form a volumetric representation of solid body 115A. Polyhedral mesh 115 may be defined for solid body 115A by any suitable mesh generation techniques commonly used in FEM, such as TetGen, NETGEN, Gmsh and/or the like, for example. Polyhedral mesh 115 may comprise a plurality of vertices, a plurality of edges connecting the vertices, and a plurality of faces or polygons defined by the edges. The outer polygonal faces of these polyhedral elements of mesh 115 collectively define the shape of solid body 115A. The polygonal faces may comprise any number of edges, such as three edges to form a tetrahedral mesh with triangular faces, or four edges to form a cuboid mesh with quadrilateral faces. In some embodiments, polyhedral mesh 115 may be provided as an input to method 100 and method 100 does not require a separate step for defining mesh 115.

After defining mesh 115 at block 110, method 100 proceeds to optional block 120, which comprises determining an optimal time step 125 at which vertex displacement calculations are repeated during the method 100 simulation. As described in greater detail herein, it may be desirable at block 120 to employ a time step which produces the largest movement possible, while conserving physical invariants (e.g. during quasi-static sub-steps, which may be considered to be dynamic steps with low strain rate, it may be desirable to conserve the physical invariants of momentum and total energy). By virtue of the integration techniques used in method 100, as discussed further herein, large time steps may be taken without fear that the simulation becomes unstable, as vertices are moved only to physically valid configurations. However, when taking large time steps, there may be a significant amount of numerical damping that occurs, which may adversely impact the volume preserving characteristics of the deformation simulation. On the other hand, if too small a time step 125 is selected, then the sub-steps may move unacceptably slowly towards the quasi-static solution. It will be appreciated that the performance of block 120 for determining an optimal time step is not necessary and that the time step used in performing the method 100 deformation simulation can be determined by any appropriate means, including, for example, by estimating or guessing a suitable time step or by attempting to ascertain an optimal time step in accordance with some other technique.

Method 100 then proceeds to a loop comprising blocks 130 and 140, where the deformation simulation is performed by computing, and applying, vertex (node) displacements to the polyhedral mesh 115 for successive time steps of the method 100 quasi-static simulation.

One aspect of the invention provides a method for computer-based simulation and/or animation of musculoskeletal systems using the symplectic integrator of PBD methods in conjunction with the control of material properties afforded by implicit FEM techniques. Traditional FEM solvers involve obtaining solutions for all elements (e.g. mesh nodes (vertices) or mesh polyhedrons) at once. Specifically, FEM solvers obtain a global solution for all node (vertex) displacements using an optimization algorithm (e.g. often referred to as a solver). As an illustrative example, an example FEM algorithm may comprise a recursive process of first obtaining an initial mesh solution, considering a refinement strategy from the initial coarse mesh, applying the refinement strategy to minimize a measure of error (e.g. a cost function or the like), and performing subsequent iterations to achieve a desired accuracy. FEM solutions can be obtained either through implicit analysis or explicit analysis. In the case of explicit analysis, the FEM solver considers only the current state of the mesh system to arrive at updated nodal velocity and displacement estimates. The explicit scheme is not unconditionally stable and thus relatively small time steps are typically used to ensure accuracy. In the case of implicit analysis, the FEM solver involves solving for both current and future states of a given mesh system. This implicit FEM scheme is resultantly unconditionally stable, but may also be computationally costly with its use of advanced global solvers.

In contrast to both explicit and implicit FEM analyses, the semi-implicit, or symplectic, integrator of PBD calculates the vertex displacement estimates for each vertex in an element-by-element fashion and then iteratively projects one or more positional constraints on the initial displacement estimates using a constraint-projection solver algorithm. The PBD solver tries to modify the displacement estimates, such that all of the projected constraints are satisfied. Using a Gauss-Seidel-type process (augmented by a Lagrange multiplier constraint solver, in some cases), the PBD solver iterates through the constraints and applies them to the relevant vertices at each iteration. Convergence of PBD solutions can typically be achieved relatively quickly (when compared to FEM analysis). The performance of constraint solver iterations places the PBD method within the class of semi-implicit Euler, or symplectic, integration schemes, which have benefits over standard explicit Euler methods in providing a guarantee of stability.

The inventors believe that the combination of the symplectic integrator of PBD with the material model from global FEM techniques provides advantages of having strong control over material properties in the context of a stable and efficient symplectic integrator. Specifically, the FEM material model from global FEM (e.g. in the form of an implicit Euler integrator) is shown to be compatible with the Lagrange multiplier constraint solver of PBD. It is believed by the inventors that the fixed points (i.e. the state space) of both solvers, when employed in a quasi-static context, are contained in the same convex set. The intersection of the state space of both methods allow for them to be seamlessly combined. Alternatively, even if the fixed points were not actually in the same convex set, there should exist a reasonable projection between the two convex sets, such that their combination remains appropriate. Stated another way, the inventors believe that there exists a PBD constraint projection equivalent to the locally implicit FEM update for a given element.

The position update step of the symplectic PBD integrator may employ the Störmer-Verlet method in the form of:

$${x}_{i + 1} = 2 {x}_{i} - {x}_{i - 1} + 0.5 a ( {x}_{i} ) Δ {t}^{2} \qquad ( 1 )$$

where xᵢ is the current position of a vertex, xᵢ₋₁ is the position of the vertex at a previous time step, xᵢ+1 is the updated position of the vertex at a subsequent time step, Δt is the time step, and α(xᵢ) is the current acceleration of the vertex. By expanding Equation (1) so that the velocity update appears explicitly and by replacing the acceleration term with a function mapping current positions to position updates due to external forces, the position update step of Equation (1) may take the form of:

$${x}_{i + 1} = {x}_{i} + ( {x}_{i} - {x}_{i - 1} ) \frac{Δ t}{Δ t} + forces ( {x}_{i} ) \qquad ( 2 )$$

Equation (2) represents a typical position update step in PBD methods. Because the present methods focus on the quasi-static simulation of deformable solid bodies for use in CGI production (e.g. in a CGI production pipeline), where gravity is typically already accounted for by modellers, the effect of external forces can be ignored and thus the force term (the third term on the right hand side of equation (2)) can be omitted.

Despite ignoring the effects of external forces, internal forces should still be considered. By modifying Equation (2) to use the implicitly updated position state, the effects of internal forces are accounted for. In other words, the velocity term (xᵢ−xᵢ₋₁)/Δt in equation (2) can be replaced with (xᵢ₊₁−xᵢ)/Δt, or νᵢ₊₁. By applying this assumption and using the updated position, some accuracy may be lost. However, this is generally not of great concern, as acceptable accuracy can still be achieved and perfect accuracy is not the primary aim of the animation methods described herein. This can be viewed similarly to how velocity is commonly estimated in the Störmer-Verlet method, but the time step window is shifted forward in the current scenario rather than backwards. Accordingly, Equation (2) can be re-arranged and expressed in the form of:

$${v}_{i + 1} = \frac{( {x}_{i + 1} - {x}_{i} )}{Δ t} \qquad ( 3 )$$

which embodies a finite difference formula relating velocity to positions.

The implicit Euler integration step of a global FEM solver expressed as a recurrence relation may take the form of:

$${v}_{i + 1} = {v}_{i} - K {M}^{- 1} Δ {tx}_{i + 1} - γ {KM}^{- 1} Δ {tv}_{i + 1} \qquad ( 4 )$$

where: K is a matrix containing the stiffness at different elements of the object model and which converts position to a force, M is the mass matrix containing the mass of different elements, νᵢ is the current velocity of all the vertices of the mesh, νᵢ₊₁ is the updated velocity of the vertices at the subsequent time step, xᵢ₊₁ is the updated position of the vertices at the subsequent time step, Δt is the time step, and γ is a scalar damping constant. The last term of Equation (4) represents the internal damping part of Rayleigh damping used in FEM techniques for reducing high frequency noise. Equation (4) encodes an implicit Euler integration by having the velocity update term νᵢ₊₁ on both sides of the equation. The arbitrary definition of K̅=KM⁻¹Δt assists in improving the clarity of subsequent equations defined herein.

The PBD velocity relation of Equation (3) can be combined with the FEM implicit Euler integration of Equation (4). After re-arranging, the combined equations may take the form of:

$${x}_{i + 1} = {x}_{i} + Δ t - Δ t \overline{K} {x}_{i + 1} - γ \overline{K} ( {x}_{i + 1} - {x}_{i} ) ) \qquad ( 5 )$$

After collecting the terms of Equation (5) and simplifying, a linear system to solve for a position update xᵢ₊₁ can be obtained:

$$( I + Δ t \overline{K} + γ \overline{K} ) {x}_{i + 1} = {x}_{i} + Δ {tv}_{i} + γ \overline{K} {x}_{i} \qquad ( 6 )$$

where I is the identity matrix. Equation (6) may be solved for obtaining the position update xᵢ₊₁ of each vertex on an element-by-element basis in conjunction with the symplectic PBD integrator of PBD, wherein Equation (6) additionally comprises (in the K̅ term) the object's material model. In other words, the implicit Euler integration step of Equation (4) (from FEM) is combined with the finite difference velocity approximation of Equation (3) (from PBD). This establishes a relationship between the two methods (FEM and PBD). The fixed point of this combined method (using PBD constraints and FEM constraints in combination) is a fixed point of the uncombined methods (i.e. using PBD constraints and then subsequently solving an FEM system).

A concept in PBD methods is the definition of constraints which inform the possible positions of vertices. Such constraints may include, for example, collision constraints which are provided to define interactions for when the object being simulated collides with other objects and/or with itself. As an illustrative example, a symplectic PBD integrator may perform the following broad steps for simulating position updates in deformed objects:
1) For all vertices in a mesh representation of the object, initialize vertex parameters. The vertex parameters may comprise a position, velocity, and mass for each vertex.
2) For all vertices (performed on each vertex in sequential fashion), compute an estimate for new positions of the vertices based on the present position, velocity, and mass. Optionally, where an external force cannot be expressed as a positional constraint (e.g. gravity), update the velocity at that vertex to reflect the external force.
3) Modify the position estimates to obtain a set of updated positions, such that the updated positions satisfy a set of positional constraints (sometimes referred to as constraint projection). In some embodiments, constraint projection process may be performed iteratively in a Gauss-Seidel type solver (augmented by a Lagrange multiplier constraint solver) which may involve solving each constraint independently one after the other.
4) Based on the updated positions, modify the vertices to reflect these updated positions and update the vertex velocities.

Constraints may refer broadly to any relationships used to determine a vertex's position. For example, there may be “distance constraints” which require a certain spacing between vertices to be maintained, “collision constraints” which define boundaries for a vertex's motion, “attachment constraints” requiring a vertex's position to be linked with another vertex's position within the simulation, amongst other additional or alternative possible constraint types.

The inventors have found that the constraint PBD projection step can advantageously be performed with additional consideration of the material properties of the object being deformed. By applying Equation (6) in addition to existing PBD constraints and/or in place of one or more of the PBD constraints related to material properties (e.g. PBD constraints related to elastic deformation), the global implicit integration scheme of FEM in Equation (4) may be applied in a local manner which is compatible with symplectic PBD integration. In other words, the described use of Equation (6) provides a “locally implicit” way for FEM techniques to be applied to single elements (e.g. the polyhedra or vertices of a mesh), as opposed to globally.

The locally implicit FEM methods described herein have advantages in providing the physical richness of FEM in the algorithmic structure/process of PBD. As an illustrative example, this may enable the realistic rendering and modelling of muscle, skin and tissue in CGI characters in real time and with minimal post-processing requirements. The element-by-element approach of PBD is more parallelizable and computationally efficient (e.g. can be optimized to use multiple processing threads which increases CPU utilization) compared to the global solver of FEM. Memory requirements for executing PBD simulations are also much lower than the corresponding memory requirements for executing FEM simulations. Collision constraints for a global solver in FEM typically involve using a quadratic programming solver or refactoring of the system matrix, which is prohibitively expensive for any notion of interactive rate simulation (e.g. for iteration at greater than 5 frames/second based on current computer workstations).

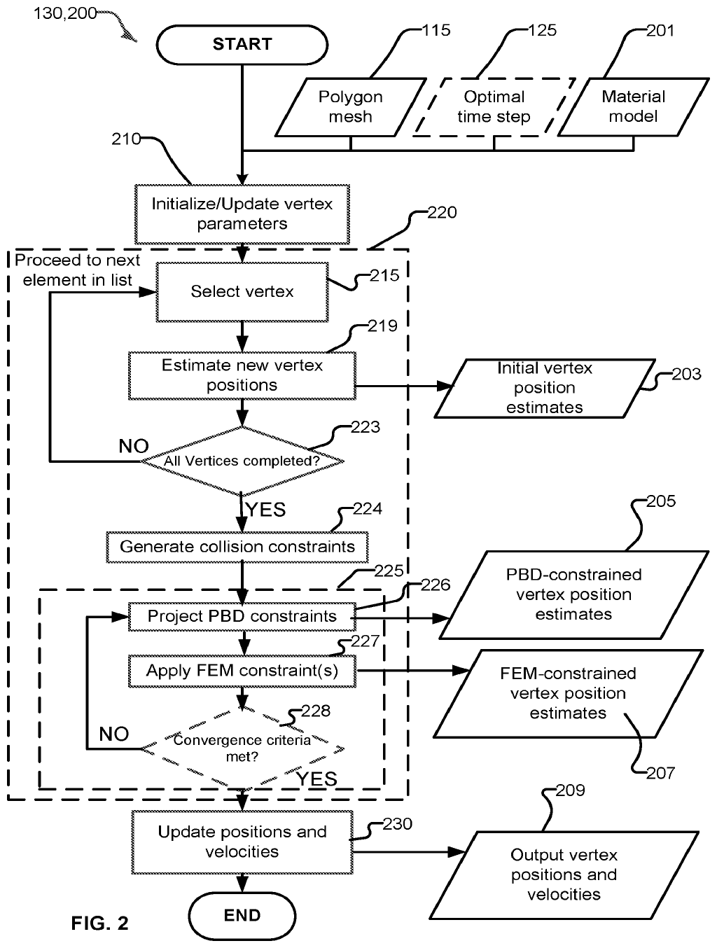

FIG. 2 schematically depicts an example method 200 which may be used at block 130 for determining node (vertex) displacements for the quasi-static FEM simulation of method 100 (FIG. 1) for one time step. Method 200 employs the “locally implicit” FEM technique described above, which uses the symplectic PBD integrator combined with the material model of FEM. Specifically, method 200 implements a PBD process where an FEM material model is incorporated (e.g. in the form of equation (6) above) as a constraint to the PBD process in the PBD constraint projection solver. Method 200 may be repeated for each time step of an animation simulation. Method 200 receives polyhedral mesh 115, optionally optimal time step 125, and material model 201 as inputs. Polyhedral mesh 115 and optimal time step 125 may be obtained from the performance of blocks 110 and 120 of method 100, respectively. Material model 201 may contain any appropriate material properties of the object being deformed and which are commonly used in FEM including, but not limited to, Lamé parameters, Young's modulus, Poisson's ratio and/or the like. According to a specific example embodiment, material model 201 comprises a corotated linear elasticity model. In other embodiments, material model 201 comprises as-rigid-as-possible (ARAP) energy or truncated St. Venant Kirchhoff (StVK). Material model 201 may represent the soft tissue of the musculoskeletal system of a CGI character. In some embodiments, material model 201 may comprise any suitable representation of a Cauchy elastic material and/or hyperelastic material.

Method 200 begins at block 210 where vertex parameters are initialized/updated (if required). Block 210 may comprise determining a current position xⱼ, mass mⱼ, and velocity νⱼ where j is an index of the vertices j∈{1, 2, . . . . N} of the deformable object 115A (as represented by mesh 115) at the current simulation time step. In the first iteration of method 200 (block 130 of FIG. 1) the vertex parameters used in block 210 may be provided by user input or may be otherwise prescribed as the initial state of mesh 115. In subsequent iterations of block 130 of FIG. 1 (e.g. where an animation simulation involving several time steps is being performed using method 200 for each time step), the initialized values of some or all of the vertex parameters in block 210 may correspond to the values at the conclusion of a previous time step (i.e. a previous iteration of method 200 (block 130)). Specifically, as described below, position xⱼ and velocity νⱼ parameters used in block 210 may be position xⱼ and velocity νⱼ parameters 209 output from block 230 of a previous iteration of method 200.

Method 200 then proceeds to block 220 which involves estimating new vertex positions and projecting constraints (including any conventional PBD constraints associated with the simulation and at least one FEM material model constraint) to revise the estimated vertex positions. Block 220 receives, as input, the initialized vertex positions xⱼ and velocities νⱼ from block 210 and outputs new vertex positions 207 (pⱼ^{FEM}), described in more detail below.

Block 220 (as illustrated dashed lines in FIG. 2) is subdivided into a number of sub-blocks. Block 220 starts with a loop involving blocks 215, 219 and 223 which involves iterating through the vertices j∈{1, 2, . . . . N} of the mesh 115 and outputting initial vertex position estimates 203 (pⱼ) for each vertex. Estimating new vertex positions 203 in block 219 may be performed in accordance with the PBD process (e.g. as described by Mueller et al. (cited above) and/or Macklin et al. (cited above)) and may comprise updating velocities

$${v}_{j} ( e . g . {v}_{j} ← {v}_{j} + \frac{Δ {tf}_{e x t} ( {x}_{j} )}{{m}_{j}} )$$

to account for external forces (fₑₓₜ(xⱼ)) (e.g. gravity) which cannot be converted into positional constraints or for which it is not desirable to include the external forces in the form of positional constraints, optionally damping velocities (if desired) and then obtaining initial vertex position estimates 203 (pⱼ) for each vertex (e.g. according to pⱼ←xⱼ+Δtνⱼ).

After iterating through all vertices and obtaining initial position estimates 203 (pⱼ) for each vertex j∈{1, 2, . . . . N}, the block 223 inquiry is positive and method 200 proceeds to block 224 which involves generating dynamic collision constraints (which may occur, for example, when a vertex moves from xⱼ to pⱼ) for all vertices j∈{1, 2, . . . . N}. The block 224 generation of dynamic collision constraints may be performed in accordance with the PBD technology (e.g. as described by Mueller et al. (cited above) and/or Macklin et al. (cited above)).

Method 200 then proceeds to block 225 which represents a PBD constraint projection process modified by the inclusion of an FEM material model. Modified PBD constraint projection process 225, shown in dashed lines in FIG. 2, starts in block 226. Block 226 represents one iteration of PBD constraint projection to obtain PBD-constrained position estimates 205 (pⱼ^{PBD}). The block 226 PBD constraint projection iteration may be performed in accordance with the PBD process (e.g. as described by Mueller et al. (cited above) and/or Macklin et al. (cited above)) and may comprise performing one iteration of projecting the block 224 collision constraints together with any static PBD constraints onto the initial vertex position estimates 203 (pⱼ) to obtain PBD-constrained position estimates 205 (pⱼ^{PBD}). The block 226 PBD constraint projection process may comprise one iteration of a PBD solver which modifies the initial vertex position estimates 203 (pⱼ) in the direction of gradients which attempt to minimize an objective function which will satisfy the PBD constraints to thereby obtain PBD-constrained position estimates 205 (pⱼ^{PBD}) (e.g. in a Gauss-Seidel-type iteration, where each PBD constraint is solved independently). Linear and angular momenta may be conserved as part of the block 225 constraint projection (at least for static constraints).

Method 200 then proceeds to block 227 which involves further updating PBD-constrained position estimates 205 (pⱼ^{PBD}) to obtain FEM-constrained position estimates 207 (pⱼ^{PBD}), which incorporate the material model 201 of object 115A being simulated as prescribed by FEM. The block 227 application of FEM constraints may involve one iteration of solving an equation of the form of equation (6), which is reproduced be low for convenience:

$$( I + Δ t \overline{K} + γ \overline{K} ) {x}_{i + 1} = {x}_{i} + Δ {tv}_{i} + γ \overline{K} {x}_{i} \qquad ( 6 )$$

K̅γΔtW⁻¹=(I+ΔtK̅+γK̅)⁻¹W⁻¹ It will be appreciated that the parameter, (the physical damping) and are known (e.g. from material model 201 and optimal time step 125 or whatever other time step is used for the method 100 (FIG. 1) simulation). The matrix may be precomputed. Left multiplying each side of equation (6) by yields:

$$\overline{K} γΔ {tW}^{- 1} = {( I + Δ t \overline{K} + γ \overline{K} )}^{- 1} {W}^{- 1} {x}_{i + 1} = {W}^{- 1} ( {x}_{i} + Δ {tv}_{i} + γ \overline{K} {x}_{i} ) \qquad ( 6 a )$$

Equation (6a) may involve guarantee of momentum and energy conservation in a manner analogous to a PBD constraint projection. Equation (6a) may be computed in block 227 on a polyhedron by polyhedron basis, where i represents an index of the polyhedrons in mesh 115 and where the initial positions xᵢ of the polyhedral vertices are given by the PBD-constrained vertex positions 205 (pⱼ^{PBD}), and the velocities νᵢ of the polyhedral vertices are given by those initialized and/or updated in block 210 to solve for xᵢ₊₁ which may be output as FEM-constrained vertex positions 207 (pⱼ^{FEM}). As soon as the FEM-constrained vertex position 207 (pⱼ^{FEM}) is determined for a particular vertex (e.g. as the result of solving equation (6a) for a particular polyhedron), this FEM-constrained vertex position 207 (pⱼ^{FEM}) may be used in the place of the PBD-constrained vertex positions 205 (pⱼ^{PBD}) for subsequent computations of equation (6a) involving that vertex. For example, where computation of equation (6a) for a first polyhedron determines FEM-constrained vertex positions 207 (pⱼ^{FEM}) for a first set of vertices, a subsequent computation of equation (6a) for a subsequent polyhedron may share some of the same vertices from among the first set of vertices. In such circumstances, the FEM-constrained vertex positions 207 (pⱼ^{FEM}) of the shared vertices may be used for the initial positions xᵢ of the polyhedral vertices in the subsequent computation of equation (6a) for the subsequent polyhedron.

Block 227 concludes after iterating through each polyhedron in the mesh 115 with the output of FEM-constrained vertex positions 207 (pⱼ^{FEM}). From the perspective of the PBD algorithm and modified PBD constraint projection process 225, the equation (6a) position update applied in block 227 may behave as just another instance of PBD constraint projection analogous to those applied in block 226.

Method 200 then proceeds to block 228 which involves evaluation of whether convergence criteria are met. In current embodiments, the block 228 convergence criteria may comprise a threshold number (e.g. 1, 3, 5, 10 or 20) of iterations of the block 226 PBD constraint projection and the block 227 FEM constraint application. In other embodiments, other suitable convergence metrics may be used for the block 228 evaluation. In quasi-static simulation scenarios, a possible condition for a positive evaluation of convergence (which may be used in block 228) at each time step is for the mesh to have reached mechanical equilibrium. As a non-limiting illustrative example, mechanical equilibrium may be considered to have been reached if the amount of total aggregate magnitude of the movement of the vertices in the available degrees of freedom is lower than a threshold amount. Another non-limiting example of a convergence metric that may be used for the block 228 evaluation is based on the Euclidean norm of the residuals between the set of FEM-constrained vertex positions 207 (pⱼ^{FEM}) in successive iterations of the block 225 modified PBD process for the N vertices in the mesh 115 being simulated. The norm of residuals is a measure of the appropriateness of a fit, whereby a smaller value indicates a better fit than a larger value. In some embodiments, a positive evaluation at block 228 may involve ascertaining that the norm of the residuals is below a threshold value. Combinations of these example convergence criteria may also be used in block 228.

In some embodiments, an adaptive iteration and/or stopping strategy can be employed when evaluating convergence at decision block 228. For example, the evaluation at block 228 may consider whether collisions occur at the current time step of the deformation being simulated. Where there are few or no collisions which take place, a lower number of iterations may be required for achieving convergence. According to a specific non-limiting example embodiment where there are no collisions in the simulated deformation, method 200 may be limited to performance of only one iteration of blocks 226 and 227. In contrast, where there are numerous collisions taking place, method 200 may comprise the performance of more block 226 and block 227 iterations, wherein collision updates are interleaved between each solver iteration. In some embodiments, the desired number of block 226 and block 227 iterations performed for a particular time step and/or number/types of collisions in the deformation simulation are user configurable parameters.

If the block 228 convergence criteria are not met, then method 200 returns to block 225 for another iteration of constraint projection (in block 226) and FEM constraint application (in block 227). Eventually, the block 228 convergence criteria are met and method 200 proceeds to block 230. Block 230 involves updating the vertex positions xⱼ and velocities νⱼ for the next time step. The block 230 velocity update may be performed according to

$${v}_{j} ← \frac{( {p}_{j}^{F E M} - {x}_{j} )}{Δ t} ,$$

where xⱼ are the block 210 vertex positions and the block 230 position update may be performed according to xⱼ←pⱼ^{FEM}. As discussed above, these block 230 updated velocities νⱼ and positions xⱼ may be used as the block 210 vertex parameters for the next time step (i.e. the next iteration of method 200 (FIG. 2) or block 130 (FIG. 1)).

Method 200 described above is discussed in the context of PBD methods which are adapted to consider an FEM material model in the form of a position constraint. Specifically, sub-process 220 adopts the algorithmic structure of the PBD position update and sub-process 225 adopts the algorithmic structure of the PBD constraint projection modified to incorporate the FEM material model in the form of an additional constraint. However, it will be appreciated that the use of PBD or the particular implementation of FEM described above is not essential to the functioning of this invention. In more general terms, the present invention relates to the combination of a global position integrator which takes into account a material model (e.g. implicit FEM) with a local integrator which yields a position update (e.g. PBD).

In general, any form of position update in which the energy does not strictly increase into which a material model can be incorporated is appropriate for use in practicing the present invention. In other words, any local integrator which conserves the area in phase space no matter how large or small the step-sizes (i.e. time in the case of animation simulations) can be suitably used. In some embodiments, integrators which are contained in the broader class of projective dynamics may be used. Projective dynamics techniques rely on constraint projections with PBD being an example instance of an integrator in this class. The integration step of an FEM solver is described above using the implicit Euler method, such as in Equation (4). In other embodiments, an implicit midpoint FEM scheme incorporating the material model may be suitably used in conjunction with the methods described herein. Other modifications or variations of traditional FEM techniques incorporating the material model are also possible.

Returning to FIG. 1, after vertex (node) displacements have been computed and applied at block 130 (e.g. through the execution of method 200), method 100 proceeds to decision block 140 which evaluates whether the quasi-static simulation has been completed. Given the time step selected at block 120 (or one which is determined through a separate process), there may be a number of successive time steps for which deformation simulations are performed to achieve the quasi-static solution and to simulate the effects of any applied forces. If there are remaining time steps in the simulation and the evaluation at decision block 140 is negative, the time step is incremented and block 130 is performed for the subsequent time step. If the quasi-static simulation is complete and the evaluation at decision block 140 is positive, then method 100 ends.

By projecting the implicit Euler update of implicit FEM (e.g. equation (6)) as a positional constraint in the symplectic integrator of PBD, the position update which takes into account a material model of the object being simulated is unconditionally stable for any time step Δt in that vertices are moved only to physically valid configurations. However, as discussed, taking too large time steps may incur significant numerical damping, while too small time steps may cause method 100 to move undesirably slowly towards the quasi-static solution. In some embodiments, the effect of a material's stiffness k at a particular element (e.g. polyhedron) is non-linear, and the material stiffness may be dependent on the time step of the simulation. Numerical damping reduces the effectiveness of each dynamic substep and thus slows down convergence. When simulating using large time steps, non-linear dynamic modes of the simulation (e.g. eigenvectors of the system matrix) may be subjected to larger amounts of numerical damping compared to the linear modes. Numerical damping may have adverse effects on the volume preservation characteristics of the simulation. Numerical damping may be avoided or mitigated via suitable selection of a time step.

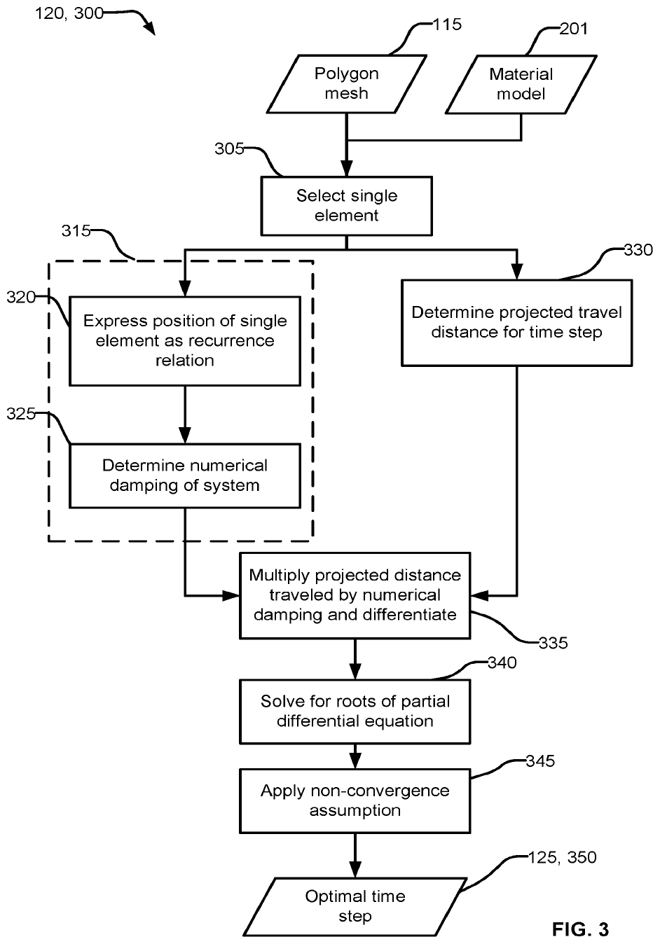

FIG. 3 schematically depicts an example method 300 which may be used at block 120 for determining an optimal time step 125 in a locally implicit FEM simulation (e.g. in animation method 100 and block 130 (FIG. 1) and/or in method 200 (FIG. 2)). Method 300 may be performed as part of block 120 (FIG. 1) for example. Method 300 receives polyhedral mesh 115 and material model 201 as inputs. Method 300 begins at block 305 which comprises selecting a single representative element of polyhedral mesh 115. An assumption underlying method 300 is that the total numerical damping of all modes in the dynamic simulation of the object 115A is in some degree proportional to or otherwise related to the local linear and non-linear modes of the single selected element. Thus, the complexity of the required analysis for finding the optimal time step can be reduced by performing an analysis of a single representative element.

Method 300 proceeds to sub-process 315, which comprises determining the numerical damping of the single-element (block 305 element) FEM system. Sub-process 315 begins at block 320 which comprises expressing the position of the single block 305 element as a recurrence relation. The inventors have found that the simplest system which behaves in a manner similar to the locally implicit FEM simulations described herein (e.g. block 130 and/or method 200) is that of an implicitly integrated spring. Such a spring can be viewed as a one-dimensional simplification of an element in the simulation. The force acting on the simplified spring element may be expressed with Hooke's law F=−kx. A simple scalar spring stiffness k is used in method 300 (rather than the stiffness matrix K representing the stiffness of different elements of the FEM system as discussed above). It will be appreciated that the scalar spring stiffness k can be extracted from the stiffness matrix K.

The implicit Euler velocity update for a spring having a stiffness k takes the form:

$${v}_{i + 1} = {v}_{i} - Δ tk {x}_{i + 1} \qquad ( 7 )$$

where xᵢ is the deflection of the particles connected to the spring from their rest length at the i^{th} time step. Expanding the terms νᵢ₊₁=xᵢ₊₁−xᵢ/Δt and νᵢ=xᵢ−xᵢ₋₁/Δt in Equation (7) and rearranging results in a position update step of the form:

$${x}_{i + 1} = \frac{( 2 {x}_{i} - {x}_{i - 1 )} )}{( 1 + k Δ {t}^{2} )} \qquad ( 8 )$$

Equation (8) can then be reorganized at block 320 to express the position of the single element as a recurrence relation of the form:

$${\underbrace{[ \begin{matrix}{x}_{i + 1} \\ {x}_{i}\end{matrix} ]}}_{Y} = {\underbrace{[ \begin{matrix}2 / ( 1 + k Δ {t}^{2} ) & - 1 / ( 1 + k Δ {t}^{2} ) \\ 1 & 0\end{matrix} ]}}_{A} {\underbrace{[ \begin{matrix}{x}_{i} \\ {x}_{i ‐ 1}\end{matrix} ]}}_{X} \qquad ( 9 )$$

Upon obtaining the recurrence relation of Equation (9) at block 320, sub-process 315 proceeds to block 325 which comprises determining the numerical damping of the single-element system. The numerical damping is found as the maximum eigenvalue from the set of eigenvalues of the matrix A from Equation (9). The eigenvalues are the scalar values A which satisfy the condition AX=Y=λX for causing Y to be a scalar multiple of X. The solution for the eigenvalues of equation (9) takes the form of:

$${λ}_{j} = \frac{1 \pm Δ t \sqrt{- k}}{1 + k Δ {t}^{2}} \qquad ( 10 )$$

where λⱼ represents the j^{th} eigenvalue, which can be simplified according to

$${λ}_{j} = \frac{1 - \sqrt{- k Δ {t}^{2}}}{1 - ( - k ) Δ {t}^{2}} = \frac{1 - \sqrt{- k Δ {t}^{2}}}{( 1 - \sqrt{- k Δ {t}^{2}} ) ( 1 + \sqrt{- k Δ {t}^{2}} )} = \frac{1}{( 1 + \sqrt{- k Δ {t}^{2}} )} ( 11 )$$

where we have elected the minus operator from the ± operator in equation (10). The solution for the eigenvalue from Equation (11) provides the spectral radius of Equation (9) and provides, as the output of sub-process 315, the numerical damping of the single-element system that is incurred for a certain stiffness k and time step Δt.

Another branch of method 300, after selecting an element at block 305, involves determining a projected travel distance for a given time step at block 330. The projected travel distance is given by the explicit Euler position update for the single-spring system in the form of:

$${x}_{i + 1} = {x}_{i} + {v}_{i} Δ t \qquad ( 12 )$$

$$where$$

$${v}_{i} = \frac{{x}_{i} - {x}_{i - 1}}{Δ t} + \int {f}_{spring} ( {x}_{i} ) d t \qquad ( 13 )$$

Using the definition for spring force f_{spring}=−kx from Hooke's law (where the lower case k spring constant takes the place of the capital K stiffness matrix of the FEM system), performing the equation (13) integration and substituting equation (12) yields:

$${x}_{i + 1} = 2 {x}_{i} - {x}_{i - 1} - ( k {x}_{i} Δ {t}^{2} ) \qquad ( 14 )$$

which provides the projected distance travelled by the element for a given time step Δt.

In general, performing deformation simulations using the largest possible time step, while minimizing the amount of numerical dampening is preferable, as taking large time steps will generally involve a smaller total number of simulations to be performed (e.g. iterations of block 130 or method 200) for reaching the quasi-static solution. Thus, the method 300 determination of an optimal time step in a locally implicit FEM simulation comprises obtaining the largest possible movement in a single time step while conserving physical invariants (i.e. conserving momentum and energy). In other words, the time step for producing the largest possible movement and which respects the conservation of momentum and/or energy is sought. A weak form of conservation of energy may also be appropriate in some embodiments, where energy may increase and decrease within certain bounds. This largest possible movement can be achieved by scaling the projected distance traveled by the numerical damping.

Method 300 proceeds to block 335, which comprises multiplying the projected block 330 travel distance by the numerical damping from block 325 and minimizing this product by differentiating with respect to time and setting the differentiated equation to zero. In some embodiments, the performance of block 335 first comprises multiplying the right hand side of Equation (14) (the distance travelled in a time step) with the right hand side of Equation (11) (the numerical damping), which, after simplifying, yields:

$$D ( x , Δ t , k ) = \frac{( 2 - k Δ {t}^{2} ) {x}_{i} - {x}_{i - 1}}{( 1 + \sqrt{- k Δ {t}^{2}} )} \qquad ( 15 )$$

Equation (15) may then be differentiated with respect to Δt while holding all other variables as fixed to obtain a partial differential equation for ∂D/∂Δt.
Method 300 proceeds to block 340 which comprises solving for the roots of the time derivative of Equation (15), or values of Δt where

$$\frac{\partial D}{\partial Δ t} = 0 .$$

Solving this differential equation in block 340 yields a number of roots having the form of:

$$Δ t = \sqrt{\frac{2 \sqrt{{x}_{i}^{3} ( 3 {x}_{i} - {x}_{i - 1} )}}{{x}_{i}^{2} k} + \frac{{x}_{i - 1}}{{x}_{i} k} - \frac{4}{k}} \qquad ( 16 )$$

A desire for optimizing the time step Δt is to address cases in which the solution is not converging quickly. In such cases, the change in position between time steps is small for certain elements and so an assumption may be applied that xᵢ≈xᵢ₋₁ at block 345. In a local solver, the most slowly converging elements are the limiting factor and the elements which converge normally will converge regardless of the time step selection. By applying the xᵢ≈xᵢ₋₁ assumption for slowly converging elements at block 345, an optimal time step can be obtained from the magnitude of Equation (16) which takes the form of:

$$Δ {t}_{optimal} = \vert \sqrt{\frac{1 - 4}{k}} \vert \approx \sqrt{\frac{3}{k}} . \qquad ( 17 )$$

By applying the stiffness K from the material model 201 for the selected element to the solution for an optimal time step of Equation (17) in accordance with the Cayley-Hamilton theorem (i.e. using the appropriate k (Young's modulus) extracted from the stiffness matrix K), an optimal time step 350 can be computed according to Equation (17). Through the performance of method 300 for obtaining an optimal time step at block 120 (of method 100), time steps which result in the largest possible movements while preserving the volume preservation characteristics of the deformation simulation may be advantageously obtained to thus improve simulation performance.

Where the stiffness of the object to be deformed is homogenous, the singular stiffness k of the object may be used at Equation (17) for determining the optimal time step. In other embodiments, particularly where the stiffness of the polyhedral mesh 115 is not homogenous, then method 100 may optionally involve a determination of an optimal material stiffness for use in determining the optimal time step. For example, an optimal stiffness may comprise a stiffness which is representative of an average stiffness of the deformable solid body and which additionally permits for the largest time step to be obtained while incurring minimal numerical damping. In some embodiments, an optimal stiffness k which can be used in equation (17) may be determined by principal component analysis (PCA).

The use of method 300 is described above in the context of obtaining an optimal time step in a locally implicit FEM simulation (through Equations (7)-(17) and method 100 of FIG. 1). However, it will be appreciated that the steps of method 300 are also applicable in other simulation contexts. In other embodiments, the steps of method 300 may be performed for obtaining an optimal time step in an implicit midpoint FEM simulation context. In more general terms, the combination (e.g. product) of a system's numerical damping (e.g. obtained through sub-process 315) with a projected travel distance (e.g. from block 330) and solving for the roots of the differentiated result (e.g. minimizing the product in blocks 335-340) may yield an optimal time step for a generic FEM simulation to be used individually or in combination with a local positional integrator. Such an optimal time step may be determined in relation to one or more elements of the system.

### Interpretation of Terms

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms.

Words that indicate directions such as “vertical”, “transverse”, “horizontal”, “upward”, “downward”, “forward”, “backward”, “inward”, “outward”, “vertical”, “transverse”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Embodiments of the invention may be implemented using specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”)). Examples of programmable data processors are: microprocessors, digital signal processors (“DSPs”), embedded processors, graphics processors, math co-processors, general purpose computers, server computers, cloud computers, mainframe computers, computer workstations, and the like. For example, one or more data processors in a control circuit for a device may implement methods as described herein by executing software instructions in a program memory accessible to the processors.

Processing may be centralized or distributed. Where processing is distributed, information including software and/or data may be kept centrally or distributed. Such information may be exchanged between different functional units by way of a communications network, such as a Local Area Network (LAN), Wide Area Network (WAN), or the Internet, wired or wireless data links, electromagnetic signals, or other data communication channel.

For example, while processes or blocks are presented in a given order, alternative examples may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times.

In addition, while elements are at times shown as being performed sequentially, they may instead be performed simultaneously or in different sequences. It is therefore intended that the following claims are interpreted to include all such variations as are within their intended scope.

Software and other modules may reside on servers, workstations, personal computers, tablet computers, image data encoders, image data decoders, PDAs, color-grading tools, video projectors, audio-visual receivers, displays (such as televisions), digital cinema projectors, media players, and other devices suitable for the purposes described herein. Those skilled in the relevant art will appreciate that aspects of the system can be practised with other communications, data processing, or computer system configurations, including: Internet appliances, hand-held devices (including personal digital assistants (PDAs)), wearable computers, all manner of cellular or mobile phones, multi-processor systems, microprocessor-based or programmable consumer electronics (e.g., video projectors, audio-visual receivers, displays, such as televisions, and the like), set-top boxes, color-grading tools, network PCs, mini-computers, mainframe computers, and the like.

The invention may also be provided in the form of a program product. The program product may comprise any non-transitory medium which carries a set of computer-readable instructions which, when executed by a data processor, cause the data processor to execute a method of the invention. Program products according to the invention may be in any of a wide variety of forms. The program product may comprise, for example, non-transitory media such as magnetic data storage media including floppy diskettes, hard disk drives, optical data storage media including CD ROMs, DVDs, electronic data storage media including ROMs, flash RAM, EPROMs, hardwired or preprogrammed chips (e.g., EEPROM semiconductor chips), nanotechnology memory, or the like. The computer-readable signals on the program product may optionally be compressed or encrypted.

In some embodiments, the invention may be implemented in software. For greater clarity, “software” includes any instructions executed on a processor, and may include (but is not limited to) firmware, resident software, microcode, and the like. Both processing hardware and software may be centralized or distributed (or a combination thereof), in whole or in part, as known to those skilled in the art. For example, software and other modules may be accessible via local memory, via a network, via a browser or other application in a distributed computing context, or via other means suitable for the purposes described above.

Where a component (e.g. a software module, processor, assembly, device, circuit, etc.) is referred to above, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology; and/or omitting combining features, elements and/or acts from described embodiments.

Various features are described herein as being present in “some embodiments”. Such features are not mandatory and may not be present in all embodiments. Embodiments of the invention may include zero, any one or any combination of two or more of such features. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible).

The invention comprises a number of non-limiting aspects. Non-limiting aspects of the invention comprise:
1. A computer-implemented method for simulating deformation of a solid body, the method comprising:
   defining and/or receiving a mesh representation of the solid body, the mesh representation comprising a plurality of vertices;
   defining and/or receiving a material model comprising one or more parameters for modeling one or more corresponding material properties of the solid body;
   for each time step in a simulation comprising one or more time steps:
      determining a subsequent position for each vertex among the plurality of vertices at a subsequent time step, wherein determining the subsequent position for each vertex among the plurality of vertices at the subsequent time step comprises:
         defining and/or receiving a current position and a current velocity of each vertex among the plurality of vertices;
         defining a positional constraint for each vertex among the plurality of vertices based at least in part on the material model; and
         estimating the subsequent position of each vertex among the plurality of vertices based at least in part on the current position of the vertex, the current velocity of the vertex and the positional constraint for the vertex.
2. The method according to aspect 1 or any other aspect herein wherein defining the positional constraint comprises defining the positional constraint for each vertex among the plurality of vertices in a form of a position update which relates a position of the vertex at a first time step to a position of the vertex at a later time step.
3. The method of any one of aspects 1 to 2 or any other aspect herein wherein the positional constraint for each vertex among the plurality of vertices has a form of (I+ΔtK̅+γK̅)x₁₊₁=xᵢ₊₁+Δtνᵢ+γK̅xᵢ as described above in connection with equation (6).
4. The method of any one of aspects 1 to 3 or any other aspect herein wherein determining the subsequent position for each vertex among the plurality of vertices at the subsequent time step comprises application of a position based dynamics (PBD) integrator.
5. The method of any one of aspects 1 to 4 or any other aspect herein wherein determining the subsequent position for each vertex among the plurality of vertices at the subsequent time step comprises:
   computing an initial updated position estimate for each vertex among the plurality of vertices at the subsequent time step based at least in part on the current position and the current velocity of the vertex;
   defining one or more position based dynamics (PBD) constraints;
   in each iteration of an iterative constraint projection process:
      projecting the PBD constraints to arrive at PBD-constrained vertex position estimates, wherein projecting the PBD constraints comprises, for each vertex among the plurality of vertices, starting with the initial updated position estimate and moving a position of the vertex in directions which tend to satisfy the one or more PBD constraints to provide a PBD-constrained vertex position;
      applying the positional constraints to arrive at FEM-constrained position estimates, wherein applying the positional constraints comprises, for each vertex among the plurality of vertices, starting with the PBD-constrained vertex position and moving the position of the vertex in accordance with the positional constraint to provide a FEM-constrained vertex position;
   at the conclusion of the iterative constraint projection process determining the subsequent position for each vertex among the plurality of vertices at the subsequent time step to be the FEM-constrained vertex position of the vertex after a last iteration of applying the positional constraints.
6. The method of aspect 5 or any other aspect herein wherein a number of iterations in the iterative constraint projection process is based on a number of iterations experimentally determined to satisfy one or more criteria.
7. The method of any one of aspects 5 to 6 or any other aspect herein wherein the number of iterations experimentally determined to satisfy one or more criteria is user-configurable by setting a first threshold number of iterations, qualitatively or quantitatively assessing convergence, and then setting a second threshold number (larger than the first threshold number) of iterations and continuing to iteratively perform the constraint projection process until reaching the second threshold number of iterations.
8. The method of any one of aspects 1 to 4 or any other aspect herein wherein determining the subsequent position for each vertex among the plurality of vertices at the subsequent time step comprises:
   computing an initial updated position estimate for each vertex among the plurality of vertices at the subsequent time step based at least in part on the current position and the current velocity of the vertex;
   defining one or more constraints, wherein the one or more constraints include the positional constraints;
   projecting the one or more constraints, wherein projecting the one or more constraints comprises, for each vertex among the plurality of vertices, starting with the initial updated position estimate and iteratively moving a position of the vertex to satisfy the one or more constraints, with each iteration providing an updated vertex position;
   determining subsequent position for each vertex among the plurality of vertices at the subsequent time step to be the updated vertex position of the vertex after the last iteration of moving the position of the vertex to satisfy the one or more constraints.
9. The method of aspect 8 or any other aspect herein wherein a number of iterations in the iterative projecting of the one or more constraints is based on a number of iterations experimentally determined to satisfy one or more criteria.
10. The method of any one of aspects 8 to 9 or any other aspect herein wherein the number of iterations experimentally determined to satisfy one or more criteria is user-configurable by setting a first threshold number of iterations, qualitatively or quantitatively assessing convergence, and then setting a second threshold number (larger than the first threshold number) of iterations and continuing the iterative projecting of the one or more constraints until reaching the second threshold number of iterations.
11. The method of any one or aspects 1 to 10 or any other aspect herein wherein defining the positional constraint for each vertex among the plurality of vertices based at least in part on the material model comprises:
   modifying a Störmer-Verlet integrator by representing a velocity term using an implicitly updated position state;
   combining an implicit Euler integrator comprising the material model with the modified Störmer-Verlet integrator; and
   solving a linear system of the combined integrators to obtain a position update equation representing the positional constraint based on the material model.
12. A method according to aspect 11 or any other aspect herein wherein representing the velocity term of the Störmer-Verlet integrator using an implicitly updated position state has the form of

$${v}_{i + 1} = \frac{( {x}_{i + 1} - {x}_{i} )}{Δ t} ,$$

as described above in connection with Equation (3).
13. A method according to any one of aspects 11 to 12 or any other aspect herein wherein the implicit Euler integrator of an FEM solver has the form of νᵢ₊₁=νᵢ−KM⁻¹ Δtxᵢ₊₁−γKM⁻¹Δtνᵢ₊₁, as described above in connection with Equation (4).
14. A method according to any one of aspects 11 to 13 or any other aspect herein wherein the linear system of the combined integrators has the form of (I+ΔtK̅+γK̅)xᵢ₊₁=xᵢ+Δtνᵢ+γK̅xᵢ, as described above in connection with Equation (6).
15. A method according to any one of aspects 1 to 4 or any other aspect herein wherein the material model comprises a material model suitable for use in implicit FEM.
16. A method according to any one of aspects 1 to 15 or any other aspect herein wherein the positional constraint based on the material model enforces one or more of:
   Lamé parameters;
   Young's modulus; and
   Poisson's ratio;
of the solid body.
17. A method according to any one of aspects 1 to 16 or any other aspect herein wherein the material model comprises a corotated linear elasticity model.
18. A method according to any one of aspects 1 to 17 or any other aspect herein wherein the material model comprises a Cauchy elastic model.
19. A method according to any one of aspects 1 to 18 or any other aspect herein wherein the material model comprises a hyperelastic material model.
20. A computer-implemented method of simulating deformation of a solid body, the method comprising:
   defining a mesh representation of the solid body, the mesh representation comprising a plurality of polyhedral mesh elements, each polyhedral mesh element defined by a plurality of vertices,
   receiving a material model comprising one or more material properties of the solid body;
   for each of the plurality of vertices defining the plurality of polyhedral mesh elements, determining a subsequent position of the vertex at a subsequent time step, wherein determining the subsequent position of the vertex at the subsequent time step comprises:
   defining a current position and a current velocity of the vertex;
   defining a positional constraint of the vertex based on the material model; and
   computing a subsequent position of the vertex based on at least the current position, the current velocity and the positional constraint.
21. A method according to aspect 20 or any other aspect herein wherein defining the positional constraint based on the material model comprises:
   modifying a Störmer-Verlet integrator by representing a velocity term using an implicitly updated position state;
   combining an implicit Euler integrator comprising the material model with the modified Störmer-Verlet integrator; and
   solving a linear system of the combined integrators to obtain a position update representing the positional constraint based on the material model.
22. A method according to aspect 21 or any other aspect herein wherein representing the velocity term of the Störmer-Verlet integrator using an implicitly updated position state has the form of

$${v}_{i + 1} = \frac{( {x}_{i + 1} - {x}_{i} )}{Δ t} ,$$

as described above in connection with Equation (3).
23. A method according to any one of aspects 21 to 24 or any other aspect herein wherein the implicit Euler integrator of an FEM solver has the form of νᵢ₊₁=νᵢ−KM⁻¹Δtx₁₊₁−γKM⁻¹Δtνᵢ₊₁, as described above in connection with Equation (4).
24. A method according to any one of aspects 21 to 23 or any other aspect herein wherein the linear system of the combined integrators has the form of (I+ΔtK̅+γK̅)xᵢ₊₁=xᵢ+Δtνᵢ+γK̅xᵢ, as described above in connection with Equation (6).
25. A method according to any one of aspects 20 to 24 or any other aspect herein wherein the material model comprises a material model suitable for use in implicit FEM.
26. A method according to any one of aspects 20 to 25 or any other aspect herein wherein the positional constraint based on the material model enforces one or more of:
   Lamé parameters;
   Young's modulus; and
   Poisson's ratio;
of the solid body.
27. A method according to any one of aspects 20 to 26 or any other aspect herein wherein the material model comprises a corotated linear elasticity model.
28. A method according to any one of aspects 20 to 27 or any other aspect herein wherein the material model comprises a Cauchy elastic model.
29. A method according to any one of aspects 20 to 28 or any other aspect herein wherein the material model comprises a hyperelastic material model.
30. A method according to any one of aspects 20 to 29 wherein determining the subsequent position of the vertex at a subsequent time step comprises application of a position based dynamics (PBD) integrator.
31. A method according to aspect 30 or any other aspect herein wherein determining the subsequent position of the vertex at the subsequent time step comprises:
   computing an initial position estimate of the vertex based on at least the current position and the current velocity of the vertex;
   defining one or more constraints, wherein the positional constraint based on the material model is an instance of the one or more constraints; and
   projecting the one or more constraints, wherein projecting the one or more constraints comprises starting with the initial position estimate of the vertex and then iteratively moving a position estimate of the vertex to satisfy the one or more constraints, with each iteration providing an updated position estimate of the vertex;
   determining the subsequent position of the vertex based on the updated position estimate of the vertex after the last iteration of moving the position estimate of the vertex to satisfy the one or more constraints.
32. A method according to aspect 31 or any other aspect herein wherein the one or more constraints are projected across a plurality of vertices over a plurality of iterations for each of the plurality of vertices.
33. A method according to aspect 32 or any other aspect herein wherein a number of iterations of the plurality of iterations for each of the vertices is based on the number of iterations experimentally determined to satisfy a convergence criteria.
34. A method according to aspect 33 or any other aspect herein wherein the number of iterations experimentally determined to satisfy the convergence criteria is user-configurable by setting a first threshold number of iterations, qualitatively or quantitatively assessing convergence, and then setting a second threshold number (larger than the first threshold number) of iterations and continuing to iteratively project the constraints until reaching the second threshold number of iterations.
35. A method according to any one of aspects 1 to 34 or any other aspect herein further comprising determining an optimal time step, the time step defining an interval at which the subsequent position of each vertex among the plurality of vertices is determined.
36. A method according to aspect 35 or any other aspect herein wherein determining the optimal time step comprises:
   selecting a polyhedral mesh element from the plurality of vertices of the mesh, the mesh element having a stiffness;
   determining a numerical damping of the selected mesh element which depends on the stiffness and a selected time step;
   determining a projected travel distance which depends on a current and previous position of the mesh element, the stiffness and the selected time step;
   multiplying the projected travel distance by the numerical damping;
   differentiating the projected travel distance multiplied by the numerical damping with respect to time to yield a differentiated result; and
   solving for roots of the differentiated result.
37. A method according to aspect 36 or any other aspect herein wherein determining the optimal time step comprises applying the stiffness of the mesh element to the roots of the differentiated result.
38. A method according to any one of aspects 36 to 37 or any other aspect herein wherein determining the optimal time step comprises eliminating the current and previous position terms of the roots by applying an assumption that the current and previous position terms are equal to one another.
39. A method according to any one of aspects 36 to 38 or any other aspect here wherein the projected travel distance multiplied by the numerical damping takes the form of

$$D ( x , Δ t , k ) = \frac{( 2 - k Δ {t}^{2} ) {x}_{i} - {x}_{i - 1}}{( 1 + \sqrt{- k Δ {t}^{2}} )} ,$$

as described above in connection with Equation (15).
40. A method according to any one of aspects 36 to 39 or any other aspect herein wherein the optimal time step takes the form of

$$Δ {t}_{optimal} = \sqrt{\frac{3}{k}} ,$$

as described above in connection with Equation (17).
41. A method according to any one of aspects 36 to 40 or any other aspect herein wherein motion of the selected mesh element is modelled as an implicitly integrated spring.
42. A method according to any one of aspects 1 to 41 or any other aspect herein comprising determining a plurality of optimal time steps, each optimal time step corresponding to a group of one or more mesh elements, wherein each optimal time step defines an interval at which a subsequent position of each of the vertices belonging a group of the one or more mesh elements is determined.
43. A system for simulating deformation of a solid body, the system comprising a processor configured to:
   define and/or receive a mesh representation of the solid body, the mesh representation comprising a plurality of vertices;
   define and/or receive a material model comprising one or more parameters for modeling one or more corresponding material properties of the solid body;
   for each time step in a simulation comprising one or more time steps:
      determine a subsequent position for each vertex among the plurality of vertices at a subsequent time step, wherein determining the subsequent position for each vertex among the plurality of vertices at the subsequent time step comprises:
         defining and/or receiving a current position and a current velocity of each vertex among the plurality of vertices;
         defining a positional constraint for each vertex among the plurality of vertices based at least in part on the material model; and
         estimating the subsequent position of each vertex among the plurality of vertices based at least in part on the current position of the vertex, the current velocity of the vertex and the positional constraint for the vertex.
44. A system for simulating deformation of a solid body, the system comprising a processor, the processor configured to:
   define a mesh representation of the solid body, the mesh representation comprising a plurality of polyhedral mesh elements, each polyhedral mesh element defined by a plurality of vertices,
   receive a material model comprising one or more material properties of the solid body;
   for each of the plurality of vertices defining the plurality of polyhedral mesh elements, determe a subsequent position of the vertex at a subsequent time step, wherein determining the subsequent position of the vertex at the subsequent time step comprises:
   defining a current position and a current velocity of the vertex;
   defining a positional constraint of the vertex based on the material model; and
   computing a subsequent position of the vertex based on at least the current position, the current velocity and the positional constraint.
45 A system according to any one of aspects 43 to 44 or any other aspect herein comprising any of the features, combinations of features and/or sub-combinations of features of any of aspects 1 to 42.
46. A computer program product embodied on a non-transitory medium bearing instructions which when executed by a suitable configured processor cause the processor to perform any of the methods of any of aspects 1-42.

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

1. A computer-implemented method for simulating deformation of a solid body, the method comprising:
defining and/or receiving a mesh representation of the solid body, the mesh representation comprising a plurality of vertices;
defining and/or receiving a material model comprising one or more parameters for modeling one or more corresponding material properties of the solid body;
for each time step in a simulation comprising one or more time steps:
determining a subsequent position for each vertex among the plurality of vertices at a subsequent time step, wherein determining the subsequent position for each vertex among the plurality of vertices at the subsequent time step comprises:
defining and/or receiving a current position and a current velocity of each vertex among the plurality of vertices;
defining a positional constraint for each vertex among the plurality of vertices based at least in part on the material model; and
estimating the subsequent position of each vertex among the plurality of vertices based at least in part on the current position of the vertex, the current velocity of the vertex and the positional constraint for the vertex.

2. The method according to claim 1 wherein defining the positional constraint comprises defining the positional constraint for each vertex among the plurality of vertices in a form of a position update which relates a position of the vertex at a first time step to a position of the vertex at a later time step.

3. The method of claim 1 wherein the positional constraint for each vertex among the plurality of vertices has a form of (I+ΔtK̅+γK̅)xᵢ₊₁=xᵢ+Δtνᵢ+γK̅xᵢ as described above in connection with equation (6).

4. The method of claim 1 wherein determining the subsequent position for each vertex among the plurality of vertices at the subsequent time step comprises application of a position based dynamics (PBD) integrator.

5. The method of claim 1 wherein determining the subsequent position for each vertex among the plurality of vertices at the subsequent time step comprises:
computing an initial updated position estimate for each vertex among the plurality of vertices at the subsequent time step based at least in part on the current position and the current velocity of the vertex;
defining one or more position based dynamics (PBD) constraints;
in each iteration of an iterative constraint projection process:
projecting the PBD constraints to arrive at PBD-constrained vertex position estimates, wherein projecting the PBD constraints comprises, for each vertex among the plurality of vertices, starting with the initial updated position estimate and moving a position of the vertex in directions which tend to satisfy the one or more PBD constraints to provide a PBD-constrained vertex position;
applying the positional constraints to arrive at FEM-constrained position estimates, wherein applying the positional constraints comprises, for each vertex among the plurality of vertices, starting with the PBD-constrained vertex position and moving the position of the vertex in accordance with the positional constraint to provide a FEM-constrained vertex position;
at the conclusion of the iterative constraint projection process determining the subsequent position for each vertex among the plurality of vertices at the subsequent time step to be the FEM-constrained vertex position of the vertex after a last iteration of applying the positional constraints.

6. The method of claim 5 wherein a number of iterations in the iterative constraint projection process is based on a number of iterations experimentally determined to satisfy one or more criteria.

7. The method of claim 5 wherein the number of iterations experimentally determined to satisfy one or more criteria is user-configurable by setting a first threshold number of iterations, qualitatively or quantitatively assessing convergence, and then setting a second threshold number (larger than the first threshold number) of iterations and continuing to iteratively perform the constraint projection process until reaching the second threshold number of iterations.

8. The method of claim 1 wherein determining the subsequent position for each vertex among the plurality of vertices at the subsequent time step comprises:
computing an initial updated position estimate for each vertex among the plurality of vertices at the subsequent time step based at least in part on the current position and the current velocity of the vertex;
defining one or more constraints, wherein the one or more constraints include the positional constraints;
projecting the one or more constraints, wherein projecting the one or more constraints comprises, for each vertex among the plurality of vertices, starting with the initial updated position estimate and iteratively moving a position of the vertex to satisfy the one or more constraints, with each iteration providing an updated vertex position;
determining subsequent position for each vertex among the plurality of vertices at the subsequent time step to be the updated vertex position of the vertex after the last iteration of moving the position of the vertex to satisfy the one or more constraints.

9. The method of claim 8 wherein a number of iterations in the iterative projecting of the one or more constraints is based on a number of iterations experimentally determined to satisfy one or more criteria.

10. The method of claim 8 wherein the number of iterations experimentally determined to satisfy one or more criteria is user-configurable by setting a first threshold number of iterations, qualitatively or quantitatively assessing convergence, and then setting a second threshold number (larger than the first threshold number) of iterations and continuing the iterative projecting of the one or more constraints until reaching the second threshold number of iterations.

11. The method of claim 1 wherein defining the positional constraint for each vertex among the plurality of vertices based at least in part on the material model comprises:
modifying a Störmer-Verlet integrator by representing a velocity term using an implicitly updated position state;
combining an implicit Euler integrator comprising the material model with the modified Störmer-Verlet integrator; and
solving a linear system of the combined integrators to obtain a position update equation representing the positional constraint based on the material model.

12. A method according to claim 11 wherein representing the velocity term of the Störmer-Verlet integrator using an implicitly updated position state has the form of
$${v}_{i + 1} = \frac{( {x}_{i + 1} - {x}_{i} )}{Δ t} ,$$
as described above in connection with Equation (3).

13. A method according to claim 11 wherein the implicit Euler integrator of an FEM solver has the form of νᵢ₊₁=νᵢ−KM⁻¹Δtxᵢ₊₁−γKM⁻¹Δtνᵢ₊₁, as described above in connection with Equation (4).

14. A method according to claim 11 wherein the linear system of the combined integrators has the form of (I+ΔtK̅+γK̅)xᵢ₊₁=xᵢ+Δtνᵢ+γK̅xᵢ, as described above in connection with Equation (6).

15. A method according to claim 1 wherein the material model comprises a material model suitable for use in implicit FEM.

16. A method according to claim 1 wherein the positional constraint based on the material model enforces one or more of:
Lamé parameters;
Young's modulus; and
Poisson's ratio;
of the solid body.

17. A method according to claim 1 wherein the material model comprises a corotated linear elasticity model.

18. A method according to claim 1 wherein the material model comprises a Cauchy elastic model.

19. A method according to claim 1 wherein the material model comprises a hyperelastic material model.

20. A computer-implemented method of simulating deformation of a solid body, the method comprising:
defining a mesh representation of the solid body, the mesh representation comprising a plurality of polyhedral mesh elements, each polyhedral mesh element defined by a plurality of vertices,
receiving a material model comprising one or more material properties of the solid body;
for each of the plurality of vertices defining the plurality of polyhedral mesh elements, determining a subsequent position of the vertex at a subsequent time step, wherein determining the subsequent position of the vertex at the subsequent time step comprises:
defining a current position and a current velocity of the vertex;
defining a positional constraint of the vertex based on the material model; and
computing a subsequent position of the vertex based on at least the current position, the current velocity and the positional constraint.
